(19) United States
(12) Patent Application Publication
(10) Pub. No.: US 2024/0352600 A1
(43) Pub. Date: Oct. 24, 2024

(54) BISMUTH VANADATE ELECTRODE COMPRISING VANADIUM-FUNCTIONALIZED GRAPHENE QUANTUM DOTS AND A PREPARATION METHOD THEREOF

(71) Applicants: S-Oil Corporation, Seoul (KR); Unist (Ulsan National Institute of Science and Technology), Ulsan (KR)

(72) Inventors: Ji-Hyun JANG, Ulsan (KR); Ki-yong Yoon, Ulsan (KR); Sungwoo Kwon, Ulsan (KR); Nam Hyun Hur, Ulsan (KR); Sang Cheol Paik, Ulsan (KR)

(73) Assignees: S-Oil Corporation, Seoul (KR); Unist (Ulsan National Institute of Science and Technology), Ulsan (KR)

(21) Appl. No.: 18/331,769

(22) Filed: Jun. 8, 2023

Related U.S. Application Data
(62) Division of application No. 16/932,277, filed on Jul. 17, 2020, now Pat. No. 11,713,512.

(30) Foreign Application Priority Data
Oct. 11, 2019 (KR) 10-2019-0126058

(51) Int. Cl. C25B 11/051; C25B 1/04; C25B 11/057; C25B 11/075

(52) U.S. Cl. CPC C25B 11/051; C25B 1/04; C25B 11/057; C25B 11/075

(57) ABSTRACT

The present disclosure relates to a bismuth vanadate electrode including vanadium-functionalized graphene quantum dots and a method for preparing the same. More particularly, it relates to a technology which is capable of, by adding graphene quantum dots (GQDs) in the process of immersing a bismuth vanadate (BiVO₄) electrode in an alkaline solution to remove vanadium oxide (V₂O₅) excessively formed on the surface of the electrode during its preparation, protecting the electrode from the alkaline solution as the graphene quantum dots are adsorbed onto the surface of BiVO₄ while V₂O₅ is removed, and improving the efficiency of oxygen evolution reaction (OER) when applied to a photoanode due to vanadium (V)-functionalized graphene quantum dots formed as the etched vanadium ions ((VO)₄³⁻) are adsorbed onto the graphene quantum dots.

### CROSS-REFERENCE TO RELATED APPLICATIONS

This application is a divisional application of U.S. application Ser. No. 16/932,277, filed Jul. 17, 2020, which claims priority under 35 U.S.C. § 119 to Korean Patent Application No. 10-2019-0126058 filed on Oct. 11, 2019 in the Korean Intellectual Property Office, the entireties of which are incorporated herein by reference.

### TECHNICAL FIELD

The present disclosure relates to a bismuth vanadate electrode including vanadium-functionalized graphene quantum dots and a method for preparing the same. More particularly, it relates to a technology which is capable of, by adding graphene quantum dots (GQDs) in the process of immersing a bismuth vanadate (BiVO₄) electrode in an alkaline solution to remove vanadium oxide (V₂O₅) excessively formed on the surface of the electrode during its preparation, protecting the electrode from the alkaline solution as the graphene quantum dots are adsorbed onto the surface of BiVO₄ while V₂O₅ is removed, and improving the efficiency of oxygen evolution reaction (OER) when applied to a photoanode due to vanadium (V)-functionalized graphene quantum dots formed as the etched vanadium ions ((VO)₄³⁻) are adsorbed onto the graphene quantum dots.

### BACKGROUND

With increasing energy consumption, environmental problems are increasing significantly. Development of clean, inexpensive and renewable energy sources is one of important tasks for satisfying both energy and environment problems.

Solar light, biomass and geothermal energy are presented as clean and renewable energy sources that can be satisfactory in the aspects of both energy and environment. Water splitting is a reaction mechanism whereby hydrogen gas is produced using solar energy in a photoelectrochemical (hereinafter, ‘PEC’) cell.

A PEC cell consists of two parts: a photoanode and a counter electrode. Oxygen evolution reaction (hereinafter, ‘OER’; 2H₂O→O₂+4H⁺+4e⁻) occurs at the photoanode, and hydrogen evolution reaction (hereinafter ‘HER’; 4H⁺+4e⁻→2H₂) occurs at the counter electrode.

The improvement of the performance of the PEC cell for water splitting whereby hydrogen and oxygen gases are produced by solar light is emerging as an important issue in the field of energy and environment as an inexpensive and clean energy source. Metal oxide semiconductors such as TiO₂, ZnO, Fe₂O₃ and BiVO₄ have been studied widely as photoanodes suitable for PEC water splitting systems. Bismuth vanadate (BiVO₄) is an ideal metal oxide photoanode for a PEC system due to a theoretical solar-to-hydrogen (STH) efficiency of 9.2% under air mass (AM) 1.5 G illumination, low cost, an adequate band gap (2.4 eV) for visible light absorption, and superior chemical stability in neutral electrolytes. However, because bismuth vanadate has poor charge transport and short hole-diffusion length, the PEC performance is decreased due to electron-hole recombination occurring on the surface. In addition, since bismuth vanadate is unstable in NaOH, which is an alkaline substance for removing excessively added vanadium oxide, there is also a disadvantage that high-efficiency bismuth vanadate electrodes cannot be obtained with high yield. In order to overcome these disadvantages, various strategies of using OER catalysts and using neutral or weakly basic electrolytes have been introduced. However, for preparation of high-efficiency bismuth vanadate electrodes, use of the NaOH solution which is an alkaline material for removing excess vanadium oxide is still necessary.

In order to solve this problem, research and development are keenly required on the method for effectively preparing a bismuth vanadate electrode.

The inventors of the present disclosure have identified that, by adding graphene quantum dots in the process of immersing a bismuth vanadate (BiVO₄) electrode in an alkaline solution to remove vanadium oxide (V₂O₅) excessively formed on the surface of the electrode during its preparation, the electrode can be protected from the alkaline solution as the graphene quantum dots are adsorbed onto the surface of BiVO₄ while V₂O₅ is removed, and the efficiency of oxygen evolution reaction (OER) can be improved when applied to a photoanode due to vanadium (V)-functionalized graphene quantum dots formed as the etched vanadium ions ((VO)₄³⁻) are adsorbed onto the graphene quantum dots, and have completed the present disclosure.

### SUMMARY

The present disclosure is directed to, by adding graphene quantum dots (GQDs) in the process of immersing a bismuth vanadate (BiVO₄) electrode in an alkaline solution to remove vanadium oxide (V₂O₅) excessively formed on the surface of the electrode during its preparation, protecting the electrode from the alkaline solution as the graphene quantum dots are adsorbed onto the surface of BiVO₄ while V₂O₅ is removed, and improving the efficiency of oxygen evolution reaction (OER) when applied to a photoanode due to vanadium (V)-functionalized graphene quantum dots formed as the etched vanadium ions ((VO)₄³⁻) are adsorbed onto the graphene quantum dots.

An aspect of the present disclosure relates to a bismuth vanadate electrode comprising vanadium-functionalized graphene quantum dots, which includes: (i) a bismuth vanadate (BiVO₄) electrode; and (ii) graphene quantum dots adsorbed on the surface of the bismuth vanadate electrode, wherein the graphene quantum dots are vanadium-functionalized by adsorption of vanadium ions.

Another aspect of the present disclosure relates to a photoanode including the bismuth vanadate electrode including vanadium-functionalized graphene quantum dots according to the present disclosure.

Another aspect of the present disclosure relates to a photoelectrochemical cell for water splitting, which includes the photoanode according to the present disclosure.

Another aspect of the present disclosure relates to a method for preparing a bismuth vanadate electrode including vanadium-functionalized graphene quantum dots, which includes: (a) a step of preparing a mixture solution of a NaOH solution and graphene quantum dots (GQDs); and (b) a step of immersing a BiVO₄ electrode including vanadium oxide (V₂O₅) in the mixture solution.

According to the present disclosure, by adding graphene quantum dots in the process of immersing a bismuth vanadate (BiVO₄) electrode in an alkaline solution to remove vanadium oxide (V₂O₅) excessively formed on the surface of the electrode during its preparation, the electrode can be protected from the alkaline solution as the graphene quantum dots are adsorbed onto the surface of BiVO₄ while V₂O₅ is removed, and the efficiency of oxygen evolution reaction (OER) can be improved when applied to a photoanode due to vanadium (V)-functionalized graphene quantum dots formed as the etched vanadium ions ((VO)₄³⁻) are adsorbed onto the graphene quantum dots.

### BRIEF DESCRIPTION OF DRAWINGS

FIGS. 1A to 1E show schematics of a process of preparing an existing BiVO₄ electrode in Comparative Example 1 (FIG. 1A) and a process of preparing a BiVO₄ electrode including vanadium-functionalized GQDs in Example 1 (FIG. 1B), and scanning electron microscopy (SEM) images of fluorine-doped tin oxide (FTO) with a bismuth oxyiodide (BiOI) nanosheet formed (FIG. 1C), an existing BiVO₄ electrode prepared in Comparative Example 1 (FIG. 1D) and a BiVO₄ electrode including vanadium-functionalized GQDs prepared in Example 1-2 (FIG. 1E).

FIGS. 2A to 2C show the X-ray diffraction (XRD) pattern (FIG. 2A), Raman spectra (FIG. 2B) and oxygen evolution reaction (OER) activity (FIG. 2C) of GQDs and V-GQDs for an existing BiVO₄ electrode (BiVO₄) prepared in Comparative Example 1, a GQD-including BiVO₄ electrode (GQDs/BiVO₄) prepared in Comparative Example 2 and a vanadium-functionalized GQD-including BiVO₄ electrode (V-GQDs/BiVO₄) prepared in Example 1-2.

FIGS. 3A and 3B show the photocurrent density (FIG. 3A) and Mott-Schottky plots (FIG. 3B) of an existing BiVO₄ electrode (BiVO₄) prepared in Comparative Example 1, a GQD-including BiVO₄ electrode (GQDs/BiVO₄) prepared in Comparative Example 2 and a vanadium-functionalized GQD-including BiVO₄ electrode (V-GQDs/BiVO₄) prepared in Example 1-2.

FIGS. 4A and 4B show results of comparing photocurrent density at 1.23 V_{RHE} depending on V₂O₅ etching time for an existing BiVO₄ electrode (BiVO₄) prepared in Comparative Example 1, a GQD-including BiVO₄ electrode (GQDs/BiVO₄) prepared in Comparative Example 2 and a vanadium-functionalized GQD-including BiVO₄ electrode (V-GQDs/BiVO₄) prepared in Example 1-2 (FIG. 4A) and a result of testing the stability of a V-GQDs/BiVO₄ electrode at 1.23 V_{RHE} (FIG. 4B).

FIGS. 5A to 5C show a light absorbance analysis result (FIG. 5A), a photoluminescence analysis result (FIG. 5B) and the change in the photocurrent density of V-GQDs/BiVO₄ of graphene quantum dots prepared in Preparation Examples 1-1 to 1-3 [100° C. (Preparation Example 1-1), 120° C. (Preparation Example 1-2) and 140° C. (Preparation Example 1-3); 100° C. V-GQDs/BiVO₄ (Example 1-1), 120° C. V-GQDs/BiVO₄ (Example 1-2) and 140° C. V-GQDs/BiVO₄ (Example 1-3) (FIG. 5C)].

### DETAILED DESCRIPTION OF EMBODIMENTS

Hereinafter, various aspects and exemplary embodiments of the present disclosure are described in more detail.

In the preparation process of an existing bismuth vanadate electrode, vanadium oxide (V₂O₅) formed excessively during the process is removed by immersing in NaOH, which is an alkaline solution. In this case, the production yield of the electrode is decreased due to the damage of the electrode in the alkaline solution and the efficiency of oxygen evolution reaction (OER) is also decreased. As a result, when the electrode is applied to a photoelectrochemical (PEC) cell for water splitting, the performance of the cell is decreased.

The inventors of the present disclosure have identified that, by adding graphene quantum dots in the process of immersing a bismuth vanadate (BiVO₄) electrode in an alkaline solution to remove vanadium oxide (V₂O₅) excessively formed on the surface of the electrode during its preparation, the electrode can be protected from the alkaline solution as the graphene quantum dots are adsorbed onto the surface of BiVO₄ while V₂O₅ is removed, and the efficiency of oxygen evolution reaction (OER) can be improved when applied to a photoanode due to vanadium (V)-functionalized graphene quantum dots formed as the etched vanadium ions ((VO)₄³⁻) are adsorbed onto the graphene quantum dots, and have completed the present disclosure.

An aspect of the present disclosure relates to a bismuth vanadate electrode including vanadium-functionalized graphene quantum dots, which includes: (i) a bismuth vanadate (BiVO₄) electrode; and (ii) graphene quantum dots adsorbed on the surface of the bismuth vanadate electrode, wherein the graphene quantum dots are vanadium-functionalized by adsorption of vanadium ions.

In an exemplary embodiment, in an effective peak formed in a range of 350-400 cm⁻¹ as a result of Raman spectroscopy for the bismuth vanadate including vanadium-functionalized graphene quantum dots, an intensity ratio (I_{B}/I_{A}) of the peak intensity (I_{A}) of bismuth vanadate and the peak intensity (I_{B}) of the bismuth vanadate including vanadium-functionalized graphene quantum dot may be 1.1-3. This means that the graphene quantum dots are vanadium (V)-functionalized by vanadium ions. Through this, a superior oxygen evolution reaction efficiency is achieved as compared to the existing electrode onto which graphene quantum dots are simply adsorbed.

Another aspect of the present disclosure relates to a photoanode including the bismuth vanadate electrode including vanadium-functionalized graphene quantum dots according to the present disclosure.

Another aspect of the present disclosure relates to a photoelectrochemical cell for water splitting, which includes the photoanode according to the present disclosure.

Another aspect of the present disclosure relates to a method for preparing a bismuth vanadate electrode including vanadium-functionalized graphene quantum dots, which includes: (a) a step of preparing a mixture solution of a NaOH solution and graphene quantum dots (GQDs); and (b) a step of immersing a BiVO₄ electrode including vanadium oxide in the mixture solution.

The method may further include, after the step (b), a step of washing the electrode with water and drying the same at room temperature.

The concentration of the NaOH solution may be 0.1-3 M, specifically 0.3-2 M, more specifically 0.5-1.5 M.

In another exemplary embodiment, the graphene quantum dots may be obtained through: (a-1) a step of sonicating a mixture of a carbon material and an acid; (a-2) a step of heat-treating the sonicated mixture at 80-200° C.; and (a-3) a step of cooling the heat-treated mixture and then adjusting pH to 6-9.

The carbon material may be one or more selected from a carbon fiber, a carbon nanotube, graphene, graphite, amorphous carbon, charcoal and a carbon-based material, although not being limited thereto. Specifically, a carbon fiber may be used. More specifically, a pitch-based carbon fiber may be used.

The acid may be one or more selected from sulfuric acid, nitric acid, acetic acid, hydrochloric acid, formic acid, carbonic acid and iodic acid, although not being limited thereto. Specifically, a mixture solution of sulfuric acid and nitric acid may be used.

The sonication may be performed for 30 minutes to 10 hours, specifically for 40 minutes to 5 hours, more specifically for 1-3 hours. A sonication time shorter than 30 minutes may be insufficient for making the carbon material into a nanopowder. And, a sonication time exceeding 10 hours may be economically unfavorable.

The heat treatment may be performed specifically at 90-180° C., more specifically at 100-140° C. If the heat treatment temperature is below 90° C. or above 180° C., graphene quantum dots with nonuniform particle size may be generated.

The pH may be specifically 7-8 for making the acidified graphene quantum dots basic

After the step (a-3), a step of removing ions released from the acid by conducting dialysis using a dialysis bag may be included additionally in order to prevent side reactions by the unwanted ions released from the acid.

In another exemplary embodiment, the BiVO₄ electrode including vanadium oxide may be obtained by immersing a transparent substrate with a bismuth oxyiodide (BiOI) nanosheet formed in a vanadium precursor solution and then conducting heat treatment.

The transparent substrate may be one or more selected from FTO, ZnO, ITO, AZO, GZO, IZO and IGZO, although not being limited thereto. Specifically, an FTO substrate may be used.

The vanadium precursor may be one or more selected from vanadyl acetylacetonate, ammonium metavanadate, vanadium pentoxide and vanadium trioxide, although not being limited thereto. Specifically, vanadyl acetylacetonate may be used.

The heat treatment may be performed at 300-600° C., specifically at 350-550° C., more specifically at 400-500° C., for 30 minutes to 10 hours, specifically for 40 minutes to 5 hours, more specifically for 50 minutes to 2 hours. If the heat treatment temperature is below 300° C. or if the heat temperature time is shorter than 30 minutes, BiOI may remain without being changed to BiVO₄. And, if the heat treatment temperature is above 600° C. or if the heat temperature time is longer than 2 hours, it may economically unfavorable.

In another exemplary embodiment, in the step (b), the immersion may be performed for 10-200 minutes, specifically for 15-100 minutes, more specifically for 20-40 minutes. In particular, a remarkably superior photocurrent density is achieved when the immersion is performed for 20-40 minutes as compared to when the time falls outside the range.

Although not clearly specified in the following examples or comparative examples, the inventors have investigated the loss of vanadium-functionalized graphene quantum dots for the bismuth vanadate electrodes including vanadium-functionalized graphene quantum dots according to the present disclosure prepared by varying the preparation condition of graphene quantum dots, the concentration of NaOH, the carbon material and the acid used, the preparation condition of the vanadium oxide-including BiVO₄ electrode and the immersion time in the step (b) by Raman spectroscopic analysis after measuring oxygen evolution reaction (OER) activity for 500 cycles.

As a result, it was confirmed that no loss of vanadium-functionalized graphene quantum dots adsorbed onto the photoanode was observed and no loss of vanadium adsorbed onto the graphene quantum dot was observed even after 500 cycles of OER measurement when all of the following conditions were satisfied: (i) the graphene quantum dots are obtained through (a-1) a step of sonicating a mixture of a carbon material and an acid, (a-2) a step of heat-treating the sonicated mixture at 80-200° C., and (a-3) a step of cooling the heat-treated mixture and then adjusting pH to 6-9, (ii) the concentration of the NaOH solution is 0.5-1.5 M, (iii) the carbon material is a pitch-based carbon fiber, (iv) the acid is a mixture solution of sulfuric acid and nitric acid, (v) the BiVO₄ electrode including vanadium oxide is obtained by immersing a transparent substrate with a bismuth oxyiodide (BiOI) nanosheet formed in a vanadium precursor solution and then conducting heat treatment, (vi) the transparent substrate is FTO, (vii) the vanadium precursor is vanadyl acetylacetonate, (viii) the heat treatment for preparing the BiVO₄ electrode including vanadium oxide is performed at 400-500° C. for (ix) 50 minutes to 2 hours, and (x), in the step (b), the immersion is performed for 20-40 minutes. However, when any one of the above conditions was not satisfied, the loss of vanadium-functionalized graphene quantum dots adsorbed onto the photoanode and the loss of vanadium adsorbed onto the graphene quantum dots occurred significantly after the 500 cycles of OER measurement.

Hereinafter, the present disclosure will be described in more detail through preparation examples and examples referring to the attached drawings.

### Preparation Examples 1-1 to 1-3: Preparation of Graphene Quantum Dots (GQDs)

A pitch-based carbon fiber (0.3 g) was added to a mixture solution of H₂SO₄ (60 mL) and HNO₃ (20 mL). The pitch-based carbon fiber solution was sonicated for about 2 hours and then heated at 100-140° C. (the size of graphene quantum dots is controlled depending on temperature) for 24 hours with stirring. Upon completion of reaction, the mixture was cooled to room temperature and, after adding distilled water (deionized water, 800 mL), pH was adjusted to 8 with Na₂CO₃. Graphene quantum dots dispersed in water were prepared after removing sulfate ions and nitrate ions from the acids by conducting dialysis for 3 days using a dialysis bag (retained molecular weight: 2000 Da). The heating temperature was 100° C., 120° C. and 140° C. for Preparation Examples 1-1, 1-2 and 1-3, respectively.

### Comparative Example 1: Preparation of Existing Bismuth Vanadate (BiVO₄) Electrode

A BiVO₄ electrode was prepared by a commonly known electrode preparation method. An FTO (fluorine (F)-doped tin oxide (SnO₂)) glass was washed sequentially with acetone, IPA and ethanol and then dried with nitrogen gas. Next, after mixing a 0.04 M Bi(NO₃)₃ solution with 50 mL of a 0.4 M potassium iodide (KI) solution, the solution pH was adjusted to 1.7 with HNO₃. Then, 20 mL of an anhydrous ethanol solution containing 0.23 M p-benzoquinone was mixed with the prepared solution. A bismuth oxyiodide (BiOI) nanosheet was formed on the FTO glass by conducting cathodic deposition at room temperature for 250 seconds by using FTO as a working electrode, a Pt mesh as a counter electrode and an Ag/AgCl electrode as a reference electrode, at −0.1 V vs Ag/AgCl.

Subsequently, BiOI was converted to BiVO₄ through impregnation. After immersing the FTO glass with the BiOI formed in 0.2 mL of a dimethyl sulfoxide (DMSO) solution containing 0.2 M vanadyl acetylacetonate, a BiVO₄ electrode with BiVO₄ formed and with excess V₂O₅ added on the surface was obtained by heat-treating at 450° C. (ramping rate=2° C./min) for 2 hours.

Finally, in order to remove vanadium oxide (V₂O₅) formed on the surface of BiVO₄, the BiVO₄ electrode was immersed for about 30 minutes in 100 ml of a 1 M NaOH solution, washed with water and dried at room temperature. Through this, a bismuth vanadate (BiVO₄) electrode with vanadium oxide removed was prepared.

### Comparative Example 2: Preparation of Graphene Quantum Dot-Including BiVO₄ (GQDs/BiVO₄) Electrode

After immersing the vanadium oxide (V₂O₅)-removed BiVO₄ electrode obtained in Comparative Example 1 in 100 ml of the graphene quantum dot solution prepared in Preparation Example 1-2 for about 30 minutes, followed by washing with water and drying at room temperature, a bismuth vanadate (BiVO₄) electrode with the graphene quantum dots (GQDs) adsorbed on the surface was prepared.

### Examples 1-1 to 1-3: Preparation of Vanadium-Functionalized Graphene Quantum Dot-Including BiVO₄ (V-GQDs/BiVO₄) Electrode

A bismuth vanadate (BiVO₄) electrode with vanadium-functionalized graphene quantum dots (V-functionalized GQDs) adsorbed on the surface was prepared according to the same BiVO₄ electrode preparation procedure of Comparative Example 1, except for removing V₂O₅ by immersing the BiVO₄ electrode for 30 minutes in a mixture solution of 50 mL of 1 M NaOH and 50 mL of a graphene quantum dot solution dispersed in water, followed by washing with water and drying at room temperature. For Examples 1-1, 1-2 and 1-3, the graphene quantum dots of Preparation Example 1-1 (100° C.), Preparation Example 1-2 (120° C.) and Preparation Example 1-3 (140° C.) were used, respectively.

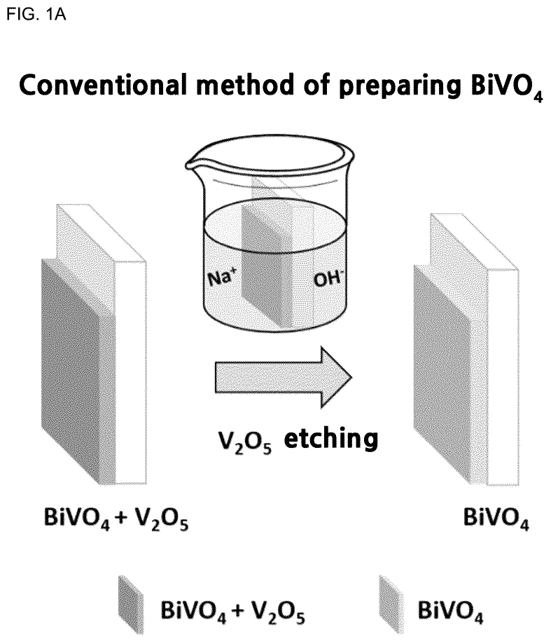

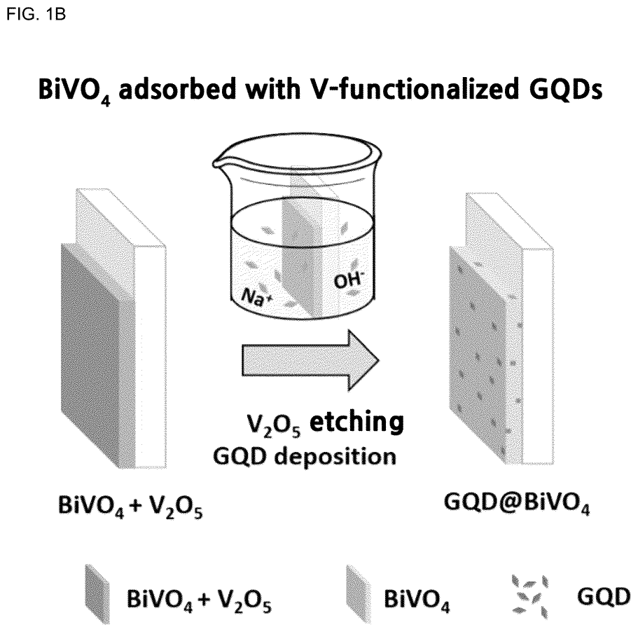

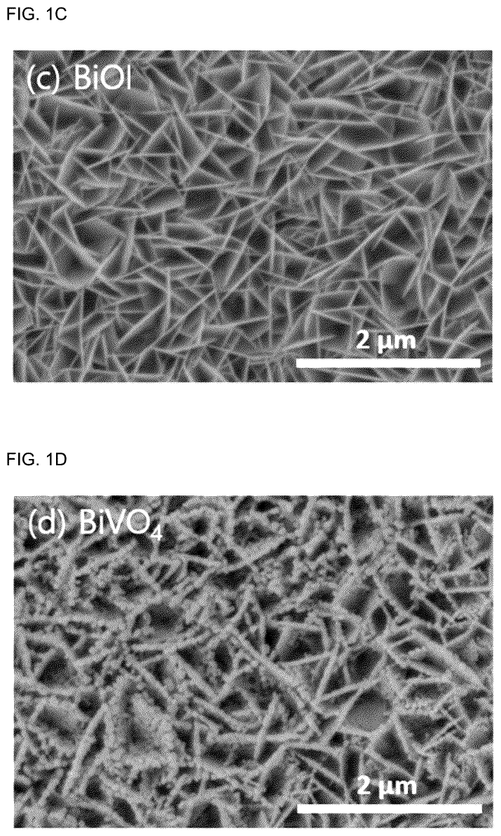

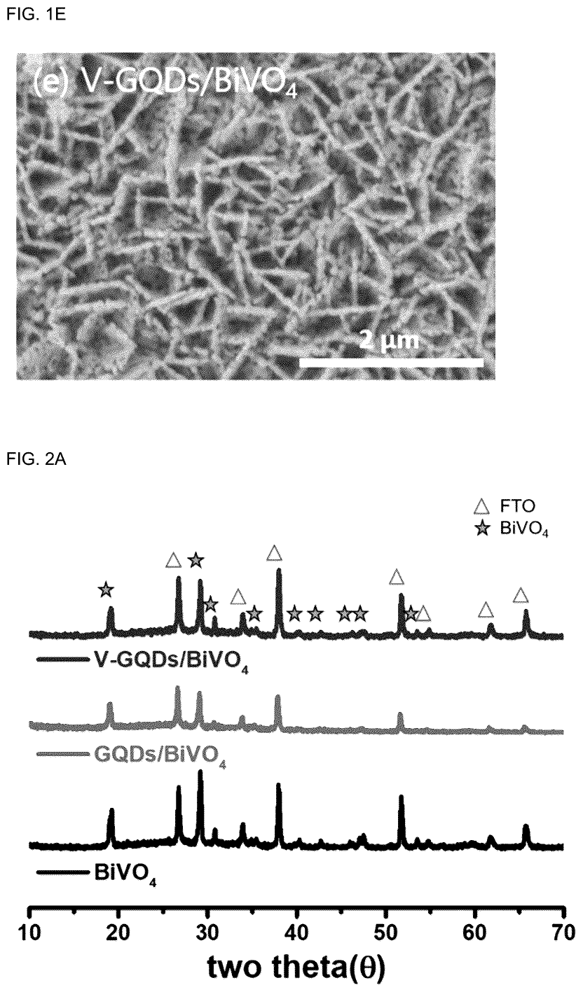

FIGS. 1A to 1E show schematics of a process of preparing the existing BiVO₄ electrode in Comparative Example 1 (FIG. 1A) and a process of preparing the BiVO₄ electrode including vanadium-functionalized GQDs in Example 1 (FIG. 1B), and scanning electron microscopy (SEM) images of the fluorine-doped tin oxide (FTO) with a BiOI nanosheet formed (FIG. 1C), the existing BiVO₄ electrode prepared in Comparative Example 1 (FIG. 1D) and the BiVO₄ electrode including vanadium-functionalized GQDs prepared in Example 1-2 (FIG. 1E).

FIG. 1A shows a process of removing V₂O₅ in the final step of the existing BiVO₄ electrode preparation process by immersing the electrode in a 1 M NaOH solution. Because 1 M NaOH is a strong alkaline solution with a pH above 13, the BiVO₄ electrode is damaged if it remains in the NaOH solution after V₂O₅ has been removed. FIG. 1B shows a process of etching V₂O₅ by mixing graphene quantum dots in a 1 M NaOH solution to prevent such damage. When a 1 M NaOH solution mixed with graphene quantum dots is used, the damage of the BiVO₄ electrode due to exposure to the NaOH solution can be prevented since the graphene quantum dots are adsorbed on the surface of the BiVO₄ electrode while V₂O₅ is removed. SEM measurement was made to investigate if V₂O₅ was removed well by the mixture solution of NaOH and graphene quantum dots. FIG. 1C shows the structure of the BiOI nanosheet formed on the FTO glass for preparation of the BiVO₄ electrode. From FIG. 1D, it can be seen that BiVO₄ with a porous structure is formed if a BiVO₄ electrode is prepared according to the existing method (i.e., by removing V₂O₅ in a 1 M NaOH solution). In addition, from FIG. 1E, it can be seen that V₂O₅ can be removed cleanly and the same structure as FIG. 1D can be obtained by using a mixture solution of a 1 M NaOH solution and graphene quantum dots. In general, graphene quantum dots cannot be observed by SEM because they are several nanometers is size. The SEM image confirms that V₂O₅ attached to BiVO₄ can be removed cleanly using the mixture of NaOH and graphene quantum dots.

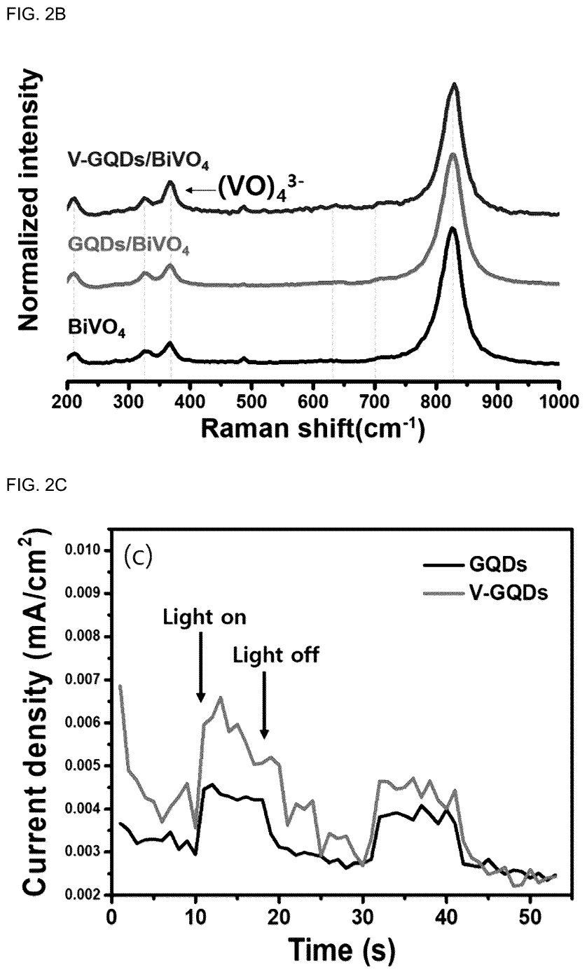

FIGS. 2A to 2C show the X-ray diffraction (XRD) pattern (FIG. 2A), Raman spectra (FIG. 2B) and oxygen evolution reaction (OER) activity (FIG. 2C) of GQDs and V-GQDs for the existing BiVO₄ electrode (BiVO₄) prepared in Comparative Example 1, the GQD-including BiVO₄ electrode (GQDs/BiVO₄) prepared in Comparative Example 2 and the vanadium-functionalized GQD-including BiVO₄ electrode (V-GQDs/BiVO₄) prepared in Example 1-2.

FIGS. 2A to 2C show the result for the existing BiVO₄ electrode (Comparative Example 1), the V-GQDs/BiVO₄ prepared using a mixture of NaOH solution and graphene quantum dots (Example 1-2) and the GQDs/BiVO₄ prepared by removing V₂O₅ according to the existing method as in Comparative Example 1 and then adsorbing GQDs in order to confirm change from GQDs to V-GQDs (Comparative Example 2). It is reported that GQDs can improve water splitting efficiency by improving oxygen evolution reaction (OER) activity on the surface of BiVO₄. From FIGS. 1A to 1E, it was confirmed that the use of a mixture of a NaOH solution and graphene quantum dots during preparation of BiVO₄ allows for removal of V₂O₅ without structural change. XRD and Raman analyses were conducted further to investigate the effect on the structure of BiVO₄.

FIG. 2A shows the crystal patterns of FTO and BiVO₄ analyzed by XRD. Graphene quantum dots are not observed in the XRD patterns because of very low crystallinity and relatively smaller amount as compared to BiVO₄. As seen from the XRD patterns, GQDs/BiVO₄ or V-GQDs/BiVO₄ had the same crystal structure as BiVO₄ and did not show the formation of a new material. This means that the removal of V₂O₅ with a mixture solution of NaOH and GQDs does not significantly affect the preparation of BiVO₄. The Raman analysis result of FIG. 2B also shows that the same signals appear at the same locations for the three materials, confirming that there is no effect on the preparation of BiVO₄. The only difference is that the signal at about 370 cm-1 in the Raman spectra is significantly stronger for V-GQDs/BiVO₄ when compared with other materials. This signal is attributable to V-GQDs, which are formed as (VO)₄³⁻ ions released from V₂O₅ by NaOH are attached to the surface of the graphene quantum dots, are adsorbed on the surface of BiVO₄. In order to confirm this, the OER activity of GQDs and V-GQDs extracted from the solution remaining after V₂O₅ etching was tested. Since GQDs are semiconductors, they have optical activity and weak water splitting can occur only with the GQDs themselves. As seen from FIG. 2C, V-GQDs extracted after V₂O₅ etching showed higher current density than GQDs. This means that the vanadium (V) ions attached to GQDs can effectively help water splitting as OER catalysts.

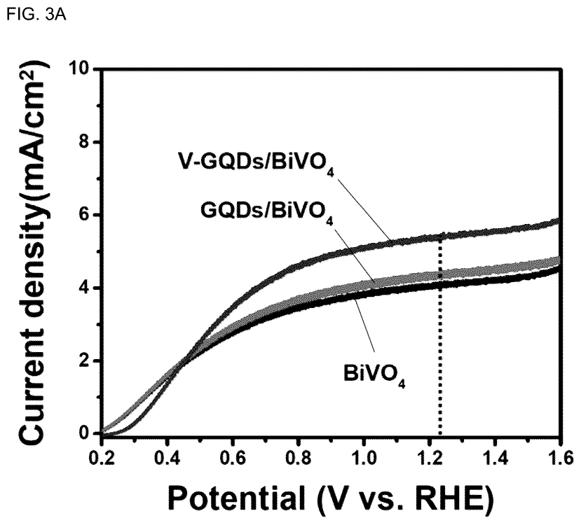

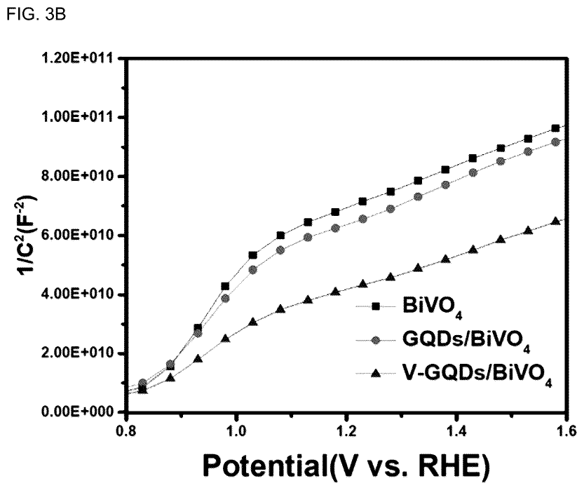

FIGS. 3A and 3B show the photocurrent density (FIG. 3A) and Mott-Schottky plots (FIG. 3B) of the existing BiVO₄ electrode (BiVO₄) prepared in Comparative Example 1, the GQD-including BiVO₄ electrode (GQDs/BiVO₄) prepared in Comparative Example 2 and the vanadium-functionalized GQD-including BiVO₄ electrode (V-GQDs/BiVO₄) prepared in Example 1-2.

FIGS. 3A and 3B show results of testing water splitting performance of the prepared electrodes. For the water splitting performance, a solar simulator (1 SUN) was used. Each of the prepared electrodes was used as a working electrode, a Pt mesh was used as a counter electrode, and an Ag/AgCl electrode was used as a reference electrode. Voltage was calculated versus a reversible hydrogen electrode (RHE). As an electrolyte for testing the water splitting performance, a 0.2 M borate buffer solution with a small amount of Na₂O₃ added to prevent recombination and serve as a hole scavenger was used.

As seen from FIG. 3A, the general BiVO₄ electrode showed about 4.0 mA/cm² of a photocurrent density at 1.23 V vs RHE, and the GQDs/BiVO₄ electrode showed about 10% improved photocurrent density of 4.4 mA/cm². And, V-GQDs/BiVO₄ showed about 30% improved photocurrent density of 5.3 mA/cm². These results prove that it is a more effective method of preparing a GQDs/BiVO₄ electrode providing superior water splitting efficiency than to attach GQDs after preparing BiVO₄. There are two reasons why V-GQDs/BiVO₄ exhibits superior efficiency as compared to the other two electrodes. First, GQDs adsorbed on the surface of BiVO₄ provide protection during the removal of V₂O₅, thereby minimizing damage of BiVO₄ from prolonged exposure to NaOH. Second, as described referring to FIGS. 2A to 2C, vanadium (V) ions released as V₂O₅ is removed are attached to GQDs and this vanadium functionalization increases the oxygen evolution reaction (OER) activity of GQDs. Mott-Schottky plots were investigated to more clearly confirm this phenomenon (FIG. 3B). As a result, V-GQDs/BiVO₄ showed the lowest slope, which means that the damage of BiVO₄ by NaOH is minimized, leading to increased formation of charges by BiVO₄ in response to light radiation and decreased charge-hole recombination by V-GQDs at the same time.

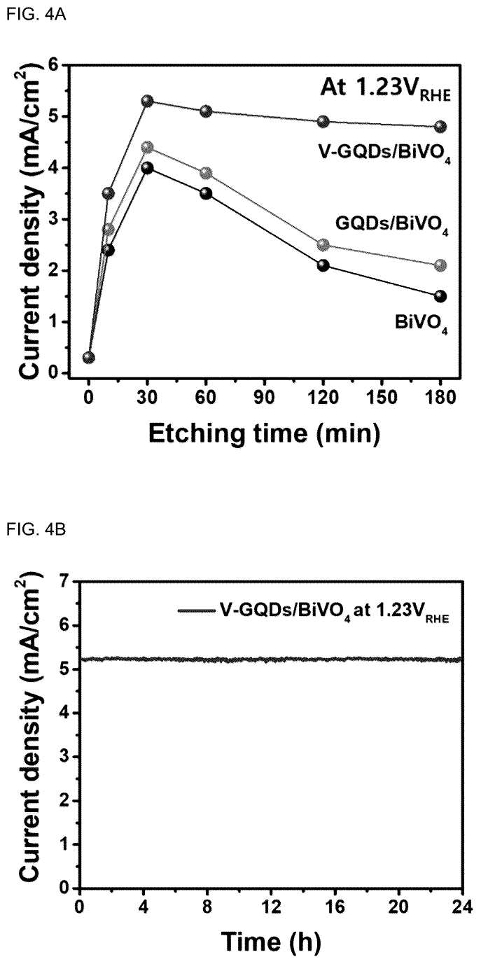

FIGS. 4A and 4B show results of comparing the photocurrent density at 1.23 V_{RHE} depending on V₂O₅ etching time for the existing BiVO₄ electrode (BiVO₄) prepared in Comparative Example 1, the GQD-including BiVO₄ electrode (GQDs/BiVO₄) prepared in Comparative Example 2 and the vanadium-functionalized GQD-including BiVO₄ electrode (V-GQDs/BiVO₄) prepared in Example 1-2 (FIG. 4A) and a result of testing the stability of the V-GQDs/BiVO₄ electrode at 1.23 V_{RHE} (FIG. 4B).

From FIGS. 1-3, it was confirmed that, when a mixture of NaOH and graphene quantum dots is used for effective removal of V₂O₅ and improvement of water splitting performance, catalytic performance is improved as GQDs are converted to V-GQDs and the damage of BiVO₄ by NaOH is decreased. In order to check this more directly, photocurrent density was tested by removing V₂O₅ with a NaOH solution with different etching time (FIG. 4A). Before etching, all the three electrodes showed low photocurrent density of about 0.3 mA/cm². This may be because the excessively added V₂O₅ fails to contact with BiVO₄ and blocks light from BiVO₄. The photocurrent density is increased gradually as V₂O₅ is etched, and all the three electrodes showed the highest efficiency when etching time was about 30 minutes. This means that V₂O₅ was removed cleanly after about 30 minutes. When the etching time exceeded 30 minutes, the photocurrent density of BiVO₄ and GQDs/BiVO₄ decreased rapidly. Through this, it can be seen that BiVO₄ was damaged by the alkaline NaOH solution. In contrast, V-GQDs/BiVO₄ showed relatively smaller decrease in efficiency. The slight decrease in efficiency is because V-GQDs are simply adsorbed in the solution and fail to completely cover the surface of BiVO₄. However, it showed very stable photocurrent density even after 30 minutes when compared with BiVO₄ or GQDs/BiVO₄. This result means that V-GQDs are adsorbed onto the surface of BiVO₄ with V₂O₅ removed and prevent BiVO₄ from being damaged by NaOH. Finally, the long-term change of photocurrent density at 1.23 V_{RHE} was monitored to investigate the stability of V-GQDs/BiVO₄ (FIG. 4B). As a result, there was no change in photocurrent density for 24 hours. This means that V-GQDs are sufficiently stable as oxygen evolution reaction (OER) catalysts.

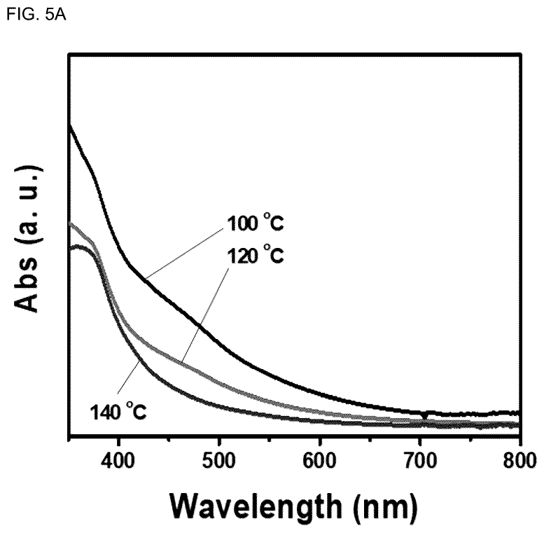

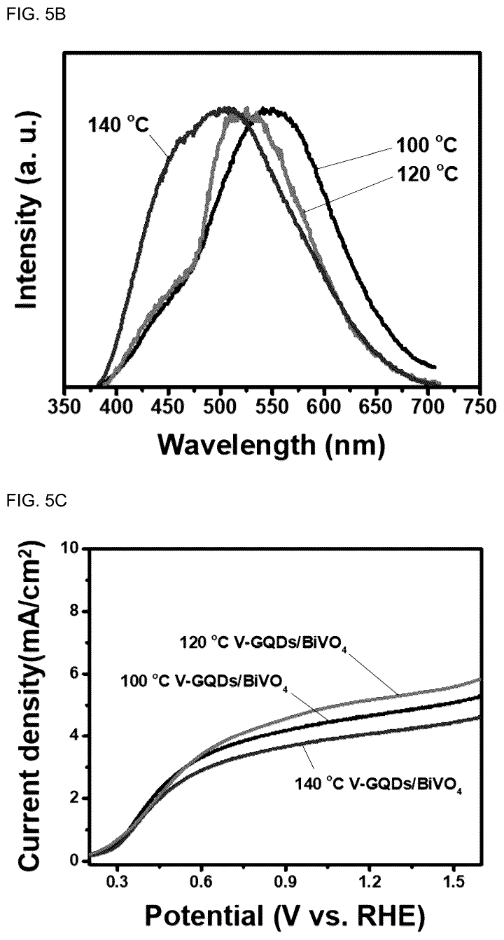

FIGS. 5A to 5C show the light absorbance analysis result (FIG. 5A), the photoluminescence analysis result (FIG. 5B) and the change in the photocurrent density of V-GQDs/BiVO₄ of the graphene quantum dots prepared in Preparation Examples 1-1 to 1-3 [(a), (b); 100° C. (Preparation Example 1-1), 120° C. (Preparation Example 1-2) and 140° C. (Preparation Example 1-3), (c); 100° C. V-GQDs/BiVO₄ (Example 1-1), 120° C. V-GQDs/BiVO₄ (Example 1-2) and 140° C. V-GQDs/BiVO₄ (Example 1-3)] (FIG. 5C).

In Example 1, the size of graphene quantum dots could be controlled with the heat treatment (oxidation cutting) temperature of the pitch-based carbon fiber. The graphene quantum dots prepared at different heat treatment temperatures or 100° C. (Preparation Example 1-1), 120° C. (Preparation Example 1-2) and 140° C. (Preparation Example 1-3) showed different light absorbance and photoluminescence. The size of graphene quantum dots can be estimated based on the light absorbance and photoluminescence measurement results and the previously reported literature (Peng, Juan, et al. “Graphene quantum dots derived from carbon fibers.” Nano Letters 12.2 (2012): 844-849). The graphene quantum dots prepared at 100° C. had a size of 7-9 nm, the graphene quantum dots prepared at 120° C. had a size of 6-8 nm, and the graphene quantum dots prepared at 140° C. had a size of 5-7 nm. In addition, the photocurrent density of the V-GQDs/BiVO₄ prepared using the graphene quantum dots was tested (FIG. 5C). The graphene quantum dots prepared at 120° C. (Example 1-2) showed the best result.

Therefore, according to the present disclosure, by adding graphene quantum dots in the process of immersing a bismuth vanadate (BiVO₄) electrode in an alkaline solution to remove vanadium oxide (V₂O₅) excessively formed on the surface of the electrode during its preparation, the electrode can be protected from the alkaline solution as the graphene quantum dots are adsorbed onto the surface of BiVO₄ while V₂O₅ is removed, and the efficiency of oxygen evolution reaction (OER) can be improved when applied to a photoanode due to vanadium (V)-functionalized graphene quantum dots formed as the etched vanadium ions ((VO)₄³⁻) are adsorbed onto the graphene quantum dots.

What is claimed is:

1. A bismuth vanadate electrode comprising vanadium-functionalized graphene quantum dots, comprising:
(i) a bismuth vanadate (BiVO₄) electrode; and
(ii) graphene quantum dots adsorbed on the surface of the bismuth vanadate electrode,
wherein the graphene quantum dots are vanadium-functionalized by adsorption of vanadium ions.

2. The bismuth vanadate electrode comprising vanadium-functionalized graphene quantum dots according to claim 1, wherein, in an effective peak formed in a range of 350-400 cm⁻¹ as a result of Raman spectroscopy for the bismuth vanadate comprising vanadium-functionalized graphene quantum dots, an intensity ratio (I_{B}/I_{A}) of the peak intensity (I_{A}) of bismuth vanadate and the peak intensity (I_{B}) of the bismuth vanadate comprising vanadium-functionalized graphene quantum dot is 1.1-3.

3. A photoanode comprising the bismuth vanadate electrode comprising vanadium-functionalized graphene quantum dots according to claim 1.

4. A photoelectrochemical cell for water splitting, comprising the photoanode according to claim 3.
